(19) United States
(12) Patent Application Publication
(10) Pub. No.: US 2026/0068505 A1
(43) Pub. Date: Mar. 5, 2026

(54) DISPLAY DEVICE

(71) Applicant: Japan Display Inc., Tokyo (JP)

(72) Inventor: Toshiharu MATSUSHIMA, Tokyo (JP)

(73) Assignee: Japan Display Inc., Tokyo (JP)

(21) Appl. No.: 19/295,724

(22) Filed: Aug. 11, 2025

(30) Foreign Application Priority Data
Aug. 29, 2024 (JP) 2024-147210

(51) Int. Cl. H10K 59/80

(52) U.S. Cl. CPC H10K 59/879; H10K 59/8722; H10K 59/8792; H10K 59/8793

(57) ABSTRACT

According to one embodiment, a display device includes a substrate, a first lower electrode, a rib layer including a first pixel aperture overlapping with the first lower electrode, a first organic layer, a first upper electrode, a resin layer, a light shielding layer provided on the resin layer and overlapping with the rib layer, a lens having a lens surface curved in a convex shape on a side opposite to the substrate, provided on the resin layer and the light shielding layer, and overlapping with the first pixel aperture, and a low refractive index layer covering a boundary between the lens surface and an upper surface of the light shielding layer, exposing an apex of the lens, and having a refractive index lower than a refractive index of the lens.

### CROSS-REFERENCE TO RELATED APPLICATION

This application is based upon and claims the benefit of priority from Japanese Patent Application No. 2024-147210, filed Aug. 29, 2024, the entire contents of which are incorporated herein by reference.

### FIELD

Embodiments described herein relate generally to a display device.

### BACKGROUND

In recent years, various forms of display devices have been proposed. For example, in display devices installed in vehicles such as automobiles, field of view angle control that enables different images to be visually recognized from the driver's side and the passenger's side is required.

### BRIEF DESCRIPTION OF THE DRAWINGS

FIG. 1 is a diagram showing a configuration example of a display device of an embodiment.

FIG. 2 is a schematic plan view showing an example of layout of subpixels.

FIG. 3 is a schematic cross-sectional view showing the display device along III-III line in FIG. 2.

FIG. 4 is a schematic plan view showing the other elements of the display device.

FIG. 5 is a schematic cross-sectional view showing the display device along V-V line in FIG. 4.

FIG. 6 is a schematic cross-sectional view showing an example of a low refractive index layer.

FIG. 7 is a schematic enlarged cross-sectional view showing a part of a lens.

FIG. 8 is a graph showing a relationship between an angle and brightness.

FIG. 9 is a schematic cross-sectional view showing another example of the low-refractive layer.

FIG. 10 is a schematic cross-sectional view showing yet another example of the low-refractive layer.

FIG. 11 is a schematic cross-sectional view showing yet another example of the low-refractive layer.

FIG. 12 is a schematic cross-sectional view showing yet another example of the low-refractive layer.

FIG. 13 is a schematic cross-sectional view showing yet another example of the low-refractive layer.

FIG. 14 is a schematic cross-sectional view showing yet another example of the low-refractive layer.

FIG. 15 is a schematic cross-sectional view showing an example in a case where a lens overlaps with a plurality of display elements.

### DETAILED DESCRIPTION

In general, according to one embodiment, a display device includes a substrate, a first lower electrode, a rib layer including a first pixel aperture overlapping with the first lower electrode, a first organic layer in contact with the first lower electrode through the first pixel aperture, a first upper electrode provided on the first organic layer, a resin layer located above the first upper electrode, a light shielding layer provided on the resin layer and overlapping with the rib layer, a lens having a lens surface curved in a convex shape on a side opposite to the substrate, provided on the resin layer and the light shielding layer, and overlapping with the first pixel aperture, and a low refractive index layer covering a boundary between the lens surface and an upper surface of the light shielding layer, exposing an apex of the lens, and having a refractive index lower than a refractive index of the lens.

According to another embodiment, a display device includes a substrate, a first lower electrode, a rib layer including a first pixel aperture overlapping with the first lower electrode, a first organic layer in contact with the first lower electrode through the first pixel aperture, a first upper electrode provided on the first organic layer, a resin layer located above the first upper electrode, a light shielding layer provided on the resin layer and overlapping with the rib layer, a lens having a lens surface curved in a convex shape on a side opposite to the substrate, provided on the resin layer and the light shielding layer, and overlapping with the first pixel aperture, and a low refractive index layer provided on the lens and the light shielding layer and having a refractive index lower than a refractive index of the lens. The low refractive index layer further has a first upper surface overlapping with the boundary between the lens surface and the upper surface of the light shielding layer, and a first end portion located on a boundary between the lens surface and the first upper surface. The first end portion is located in an area between the apex of the lens and an intersection of the lens surface and a straight line which passes through the second end portion and which is inclined at 45° relative to an optical axis of the lens.

According to the embodiments, a display device capable of limiting a viewing angle can be provided.

Several embodiments will be described hereinafter with reference to the accompanying drawings.

The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes and the like, of the respective parts are schematically illustrated in the drawings, compared to the actual modes. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

Incidentally, in the figures, an X-axis, a Y-axis and a Z-axis orthogonal to each other are described to facilitate understanding as needed. A direction along the X-axis is referred to as an X direction, a direction along the Y-axis is referred to as a Y direction, and a direction along the Z-axis is referred to as a Z direction. In addition, viewing various elements in a direction parallel to the Z-direction is referred to as plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

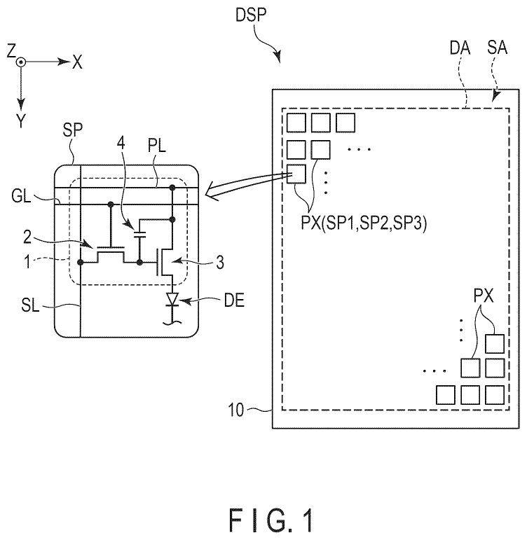

FIG. 1 is a diagram showing a configuration example of a display device DSP according to the present embodiment. The display device DSP comprises an insulating substrate 10. The substrate 10 has a display area DA where images are displayed, and a surrounding area SA around the display area DA. The substrate 10 may be glass or a resinous film having flexibility.

In the present embodiment, the substrate 10 has a rectangular shape elongated in the Y-direction in plan view. However, the shape of the substrate 10 in plan view is not limited to a rectangle, but may be the other shape such as a square, a circle or an oval.

The display area DA comprises a plurality of pixels PX arrayed in matrix in the X-direction and the Y-direction. The pixels PX include a plurality of subpixels SP displaying different colors. In the present embodiment, it is assumed that each pixel PX includes a blue subpixel SP1, a green subpixel SP2, and a red subpixel SP3. However, the pixel PX may include a subpixel SP which exhibits the other color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements consisting of thin-film transistors.

A plurality of scanning lines GL which supply a scanning signal to the pixel circuit 1 of each subpixel SP, a plurality of signal lines SL which supply a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. A drain electrode of the drive transistor 3 is connected to the display element DE.

Incidentally, the configuration of the pixel circuit 1 is not limited to the example shown in the figure. For example, the pixel circuit 1 may comprise more thin-film transistors and more capacitors.

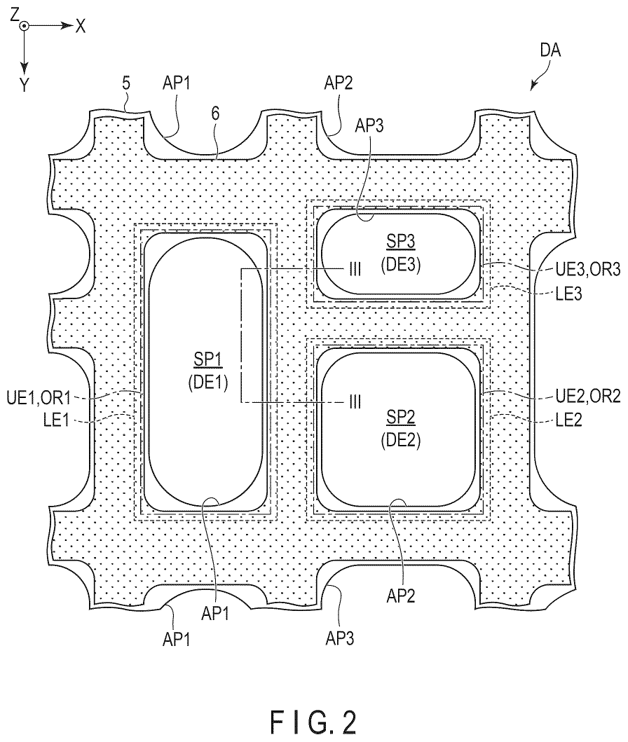

FIG. 2 is a schematic plan view showing an example of the layout of the subpixels SP1, SP2, and SP3. In the example shown in FIG. 2, each of the subpixels SP2 and SP3 is adjacent to the subpixel SP1 in the X-direction. Furthermore, the subpixels SP2 and SP3 are arranged in the Y-direction.

When the subpixels SP1, SP2, and SP3 are provided in this layout, a column in which the subpixels SP2 and SP3 are alternately provided in the Y-direction and a column in which a plurality of subpixels SP1 are repeatedly provided in the Y-direction are formed in the display area DA. These columns are alternately arranged in the X-direction. Incidentally, the layout of the subpixels SP1, SP2, and SP3 is not limited to the example shown in FIG. 2.

A rib layer 5 is provided in the display area DA. The rib layer 5 has pixel apertures AP1, AP2, and AP3 in the subpixels SP1, SP2, and SP3, respectively. In the example of FIG. 2, the pixel aperture AP1 is larger than the pixel aperture AP2, and the pixel aperture AP2 is larger than the pixel aperture AP3. In other words, among the subpixels SP1, SP2, and SP3, the aperture ratio of the subpixel SP1 is the largest, and the aperture ratio of the subpixel SP3 is the smallest. Incidentally, the size and shape of the pixel apertures AP1, AP2, and AP3 are not limited to the examples illustrated.

The subpixel SP1 comprises a lower electrode LE1 (first lower electrode), an upper electrode UE1 (first upper electrode), and an organic layer OR1 (first organic layer) each overlapping with the pixel aperture AP1 (first pixel aperture). The subpixel SP2 comprises a lower electrode LE2 (second lower electrode), an upper electrode UE2 (second upper electrode), and an organic layer OR2 (second organic layer) each overlapping with the pixel aperture AP2 (second pixel aperture). The subpixel SP3 comprises a lower electrode LE3, an upper electrode UE3, and an organic layer OR3 each overlapping with the pixel aperture AP3.

The parts of the lower electrode LE1, the upper electrode UE1, and the organic layer OR1, which overlap with the pixel aperture AP1, constitute the display element DE1 of the subpixel SP1. The parts of the lower electrode LE2, the upper electrode UE2, and the organic layer OR2, which overlap with the pixel aperture AP2, constitute the display element DE2 of the subpixel SP2. The parts of the lower electrode LE3, the upper electrode UE3, and the organic layer OR3, which overlap with the pixel aperture AP3, constitute the display element DE3 of the subpixel SP3. Each of the display elements DE1, DE2, and DE3 may further include a cap layer to be described later. The rib layer 5 surrounds each of these display elements DE1, DE2, and DE3.

A conductive partition 6 is provided in the display area DA. The partition 6 is located above the rib layer 5 and overlaps with the rib layer 5 as a whole. In the example of FIG. 2, the partition 6 has a planar shape similar to that of the rib layer 5. In other words, the partition 6 comprises an aperture in each of the subpixels SP1, SP2, and SP3. It is considered from another viewpoint that the rib layer 5 and the partition 6 have a grating shape in plan view and surround each of the display elements DE1, DE2, and DE3. The partition 6 functions as lines which apply common voltage to the upper electrodes UE1, UE2, and UE3.

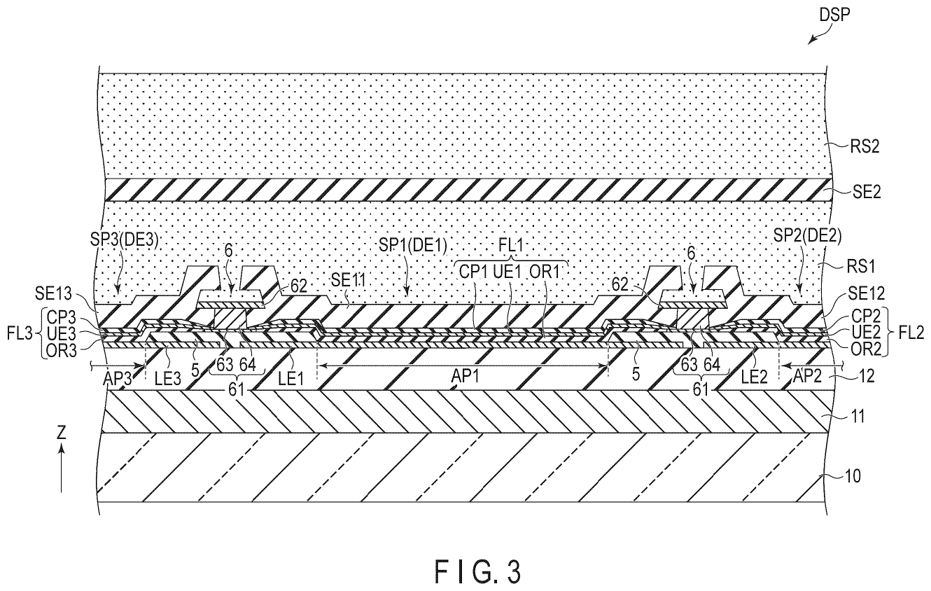

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuit 1, the scanning line GL, the signal line SL, and the power line PL, which are shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2, and LE3 are provided on the organic insulating layer 12 and are spaced apart from each other. The rib layer 5 is provided on the organic insulating layer 12 and the lower electrodes LE1, LE2, and LE3. End portions of the lower electrodes LE1, LE2, and LE3 are covered with the rib layer 5. Although not shown in the cross-section of FIG. 3, each of the lower electrodes LE1, LE2, and LE3 is connected to the pixel circuit 1 of the circuit layer 11 (the drain electrode of the drive transistor 3 shown in FIG. 1) through a contact hole provided in the organic insulating layer 12.

The partition 6 includes a conductive lower portion 61 provided on the rib layer 5 and an upper portion 62 provided on the lower portion 61. The upper portion 62 has a width greater than that of the lower portion 61. As a result, both the end portions of the upper portion 62 protrude beyond the side surfaces of the lower portion 61. This shape of the partition 6 is referred to as an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64. In addition, the end portion of the bottom layer 63 is located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower portion 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 function as optical adjustment layers for improving the extraction efficiency of the light emitted from the organic layers OR1, OR2, and OR3, respectively.

In the following descriptions, a multilayer body including the organic layer OR1, the upper electrode UE1, and the cap layer CP1 is referred to as a multilayer film FL1, a multilayer body including the organic layer OR2, the upper electrode UE2, and the cap layer CP2 is referred to as a multilayer film FL2, and a multilayer body including the organic layer OR3, the upper electrode UE3, and the cap layer CP3 is referred to as a multilayer film FL3.

Sealing layers SE11, SE12, and SE13 (first sealing layers) which cover the multilayer films FL1, FL2, and FL3, are provided in the subpixels SP1, SP2, and SP3, respectively. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 3, the sealing layer SE11 located on the partition 6 between the subpixels SP1 and SP2 is spaced apart from the sealing layer SE12 located on the partition 6. In addition, the sealing layer SE11 located on the partition 6 between subpixels SP1 and SP3 is spaced apart from the sealing layer SE13 located on this partition 6. However, two of the sealing layers SE11, SE12, and SE13 may be in contact with each other above the partition 6.

For example, a gap is formed between each of the sealing layers SE11, SE12, and SE13 and the upper portion 62 of the partition 6. The stacked films FL1, FL2, and FL3 may be provided in at least parts of these gaps.

The sealing layers SE11, SE12, and SE13 are covered with a resin layer RS1 (first resin layer). The resin layer RS1 is covered with a sealing layer SE2 (second sealing layer). The sealing layer SE2 is covered with a resin layer RS2 (second resin layer). The resin layers RS1 and RS2 and the sealing layer SE2 are continuously provided in at least the entire display area DA and partly extend to the surrounding area SA. In FIG. 3, elements located above the resin layer RS2 are omitted.

The organic insulating layer 12 is formed of an organic insulating material such as polyimide. Each of the rib layer 5 and the sealing layers SE11, SE12, SE13, and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13, and SE2 is formed of silicon nitride. Each of the resin layers RS1 and RS2 is formed of, for example, a resinous material (organic insulating material) such as epoxy resin or acrylic resin.

Each of the lower electrodes LE1, LE2, and LE3 has a reflective layer, and a pair of conductive oxide layers covering upper and lower surfaces of the reflective layer. The reflective layer can be formed of, for example, a metal material excellent in light reflectivity, such as silver. Each of the conductive oxide layers can be formed of, for example, a transparent conductive oxide such as indium tin oxide (ITO), indium zinc oxide (IZO) or indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. For example, each of the organic layers OR1, OR2, and OR3 has a structure in which a hole injection layer, a hole transport layer, an electron blocking layer, a light emitting layer, a hole blocking layer, an electron transport layer and an electron injection layer are stacked in order in the Z-direction. However, each of the organic layers OR1, OR2, and OR3 may have the other structure such as a so-called tandem structure including a plurality of light emitting layers.

Each of the cap layers CP1, CP2, and CP3 has, for example, a multilayer structure in which a plurality of transparent layers are stacked. These transparent layers may include a layer formed of an inorganic material and a layer formed of an organic material. In addition, these transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

Each of the bottom layer 63 and the stem layer 64 of the partition 6 is formed of a metal material. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or an aluminum-silicon alloy (AlSi) can be used. Incidentally, at least one of the bottom layer 63 and the stem layer 64 may have a multilayer structure consisting of a plurality of layers. Alternatively, the stem layer 64 may include a layer formed of an insulating material. For example, the upper portion 62 of the partition 6 has a multilayer structure consisting of a lower layer formed of a metal material and an upper layer formed of conductive oxide. For example, titanium, titanium nitride, molybdenum, tungsten, a molybdenum-tungsten alloy or a molybdenum-niobium alloy can be used as the metal material forming the lower layer. For the conductive oxide forming the upper layer, for example, ITO or IZO can be used.

Incidentally, the upper portion 62 may have a single-layer structure of a metal material. The upper portion 62 may further have a layer formed of an insulating material.

A common voltage is applied to the partition 6. This common voltage is applied to each of the upper electrodes UE1, UE2, and UE3 which are in contact with the side surfaces of the lower portions 61. A pixel voltage is applied to the lower electrodes LE1, LE2, and LE3 through the pixel circuits 1 provided in the subpixels SP1, SP2, and SP3, respectively, based on the video signals of the signal lines SL.

The organic layers OR1, OR2, and OR3 emit light based on the voltage application. More specifically, when a potential difference is formed between the lower electrode LE1 and the upper electrode UE1, the light emitting layer of the organic layer OR1 emits light of the blue wavelength range. When a potential difference is formed between the lower electrode LE2 and the upper electrode UE2, the light emitting layer of the organic layer OR2 emits light of the green wavelength range. When a potential difference is formed between the lower electrode LE3 and the upper electrode UE3, the light emitting layer of the organic layer OR3 emits light of the red wavelength range.

As another example, the light emitting layers of the organic layers OR1, OR2, and OR3 may emit light of the same color (for example, white). In this case, the display device DSP may comprise color filters that convert the light emitted from the light emitting layers into light of the colors corresponding to the subpixels SP1, SP2, and SP3. Alternatively, the display device DSP may comprise a layer including quantum dots which generate light exhibiting colors corresponding to subpixels SP1, SP2, and SP3 by the excitation caused by the light emitted from the light emitting layers.

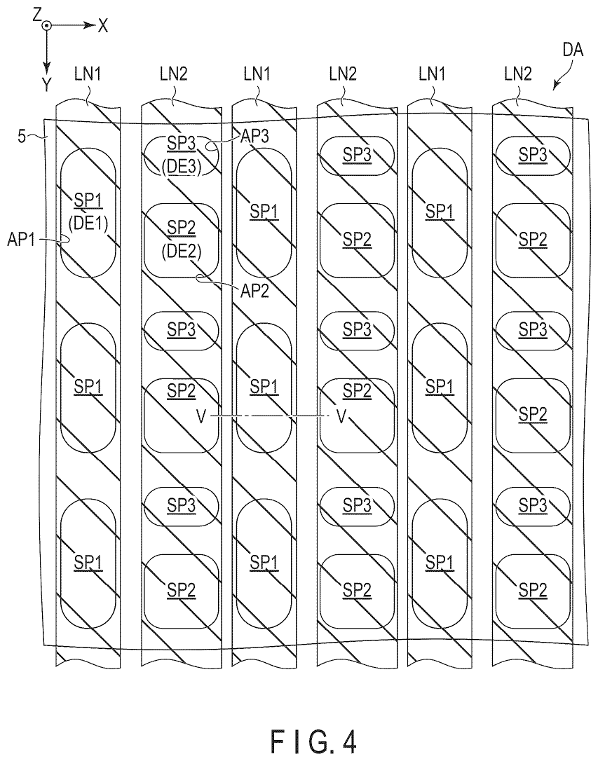

FIG. 4 is a schematic plan view showing the other elements of the display device DSP. The display device DSP further comprises lenses LN1 and LN2. The lenses LN1 and LN2 extend in the Y-direction. In the example shown in FIG. 4, the lenses LN1 overlap with a plurality of subpixels SP1 arranged in the Y-direction. In addition, the lenses LN2 overlap with a plurality of subpixels SP2 and SP3 arranged alternately in the Y-direction. In other words, the lenses LN1 overlap with the pixel apertures AP1, and lenses LN2 overlap with the pixel apertures AP2 and AP3.

Alternatively, a plurality of circular lenses overlapping with each of the subpixels SP1, SP2, and SP3 may be arranged instead of the lenses LN1 and LN2. Alternatively, a plurality of lenses continuously covering the subpixels SP1, SP2, and SP3 and extending in the Y-direction may be arranged in the X direction, instead of the lenses LN1 and LN2.

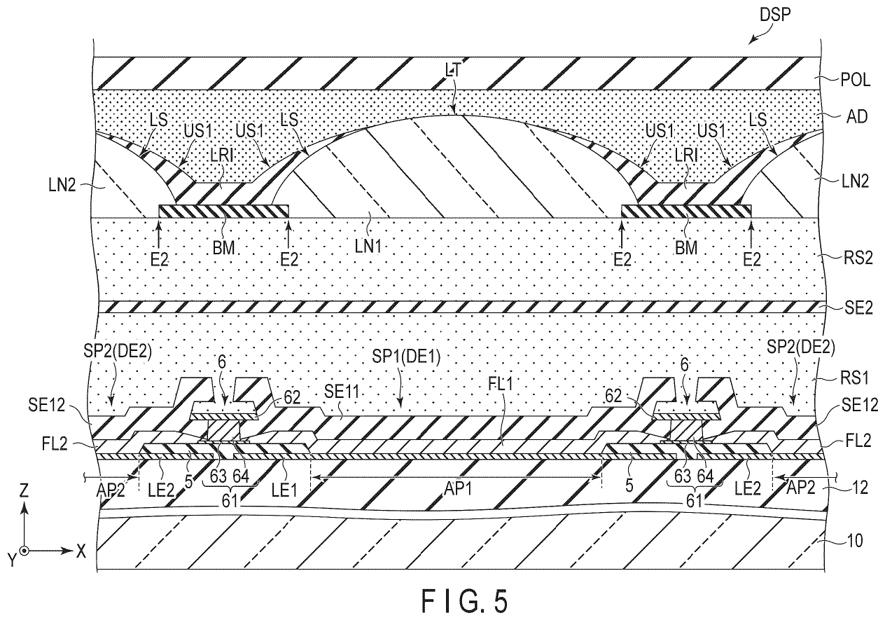

FIG. 5 is a schematic cross-sectional view showing the display device DSP along V-V line in FIG. 4. The display device DSP further comprises a light shielding layer BM, a low refractive index layer LRI, an adhesive layer AD, and a polarizer POL.

The light shielding layer BM is provided on the resin layer RS2. The light shielding layer BM overlaps with the rib layer 5 and the partition 6. End portions E2 (second end portions) of the light shielding layer BM overlap with the rib layer 5. In other words, the end portions E2 do not overlap with the pixel apertures AP1, AP2, and AP3. In one example, the light shielding layer BM is formed of a resin material with a high light absorption index.

The lenses LN1 and LN2 are provided on the resin layer RS2 and the light shielding layer BM. The end portions E2 are covered with the lenses LN1 and LN2. Each of the lenses LN1 and LN2 has a lens surface LS that is curved in a convex shape on the side opposite to the substrate 10.

The low refractive index layer LRI is provided on the light shielding layer BM and the lenses LN1 and LN2. The low refractive index layer LRI covers part of each of the lenses LN1 and LN2. In the example shown in FIG. 5, the low refractive index layer LRI covers portions of the lenses LN1 and LN2 excluding respective apexes LT of the lenses LN1 and LN2. In other words, the apexes LT are exposed from the low refractive index layer LRI. In the example shown in FIG. 5, the low refractive index layer LRI covers the light shielding layer BM and overlaps with the rib layer 5 and the partition 6 in plan view. For example, the low refractive index layer LRI is formed by methods such as slit coating or spin coating.

The low refractive index layer LRI has an upper surface US1 (first upper surface) that is curved in a convex shape on the side opposite to the substrate 10. The upper surface US1 overlaps with the lens surface LS in plan view. In one example, a curvature radius of the upper surface US1 is larger than a curvature radius of the lens surface LS.

The polarizer POL is provided above the lenses LN1 and LN2, and the low refractive index layer LRI. The adhesive layer AD bonds the low refractive index layer LRI, the lenses LN1 and LN2, and the polarizer POL. The adhesive layer AD covers the low refractive index layer LRI and the apexes LT. For the adhesive layer AD, for example, an optical clear adhesive (OCA) or the like can be used. The polarizer POL is, for example, a circular polarizer.

The refractive index of the low refractive index layer LRI is smaller than refractive indices of the lenses LN1 and LN2. In one example, the refractive index of the low refractive index layer LRI is approximately 1.3 to 1.4, and the refractive indices of the lenses LN1 and LN2 are approximately 1.6.

The refractive index of the low refractive index layer LRI is smaller than the refractive index of the adhesive layer AD. In one example, the refractive index of the adhesive layer AD is approximately 1.5.

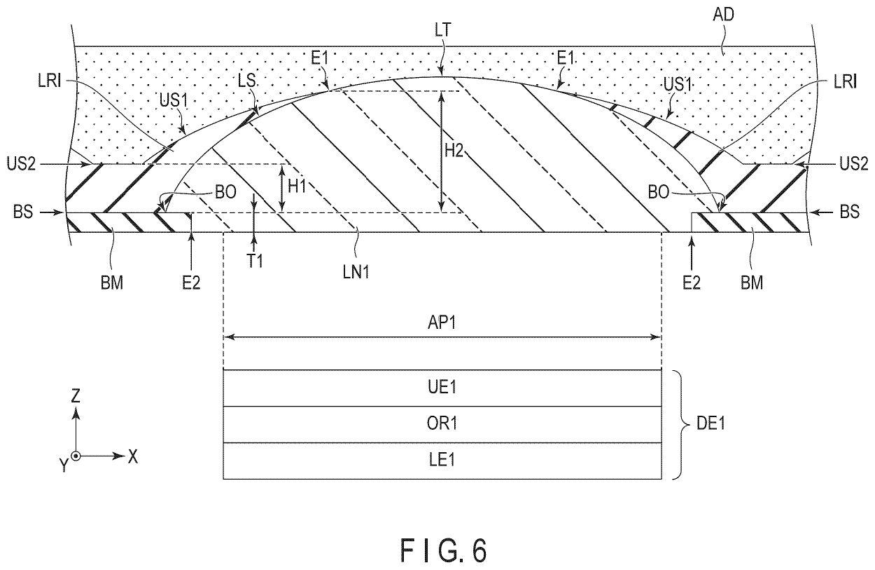

FIG. 6 is a schematic cross-sectional view showing an example of the low refractive index layer LRI.

The light shielding layer BM includes an upper surface BS covered with the lens LN1 and the low refractive index layer LRI.

The low refractive index layer LRI covers a boundary BO between the lens surface LS and the upper surface BS. The upper surface US1 overlaps with the boundary BO in plan view.

The low refractive index layer LRI further includes an end portion E1 (first end portion) located at the boundary between the lens surface LS and the upper surface US1, and a flat upper surface US2 (second upper surface). The upper surface US2 overlaps with the light shielding layer BM. The upper surface US2 is connected to the upper surface US1. In the Z-direction (the thickness direction of the substrate 10), a distance H1 from the upper surface BS to the upper surface US2 is shorter than a distance H2 from the upper surface BS to the end portion E1 (H1<H2). In the example shown in FIG. 6, the distance H1 is longer than a thickness T1 of the light shielding layer BM in the Z-direction (H1>T1).

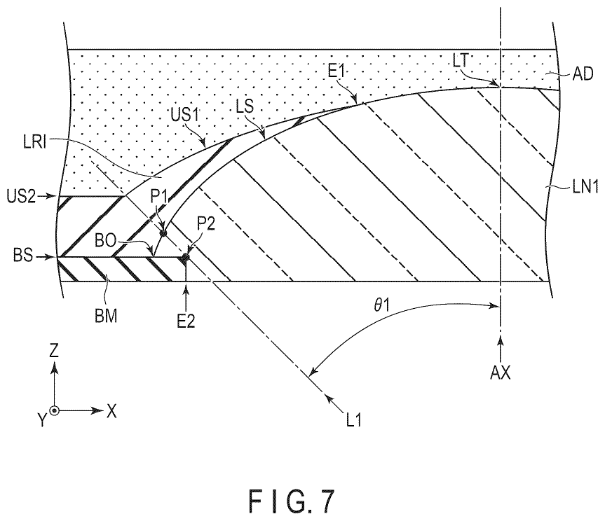

FIG. 7 is a schematic enlarged cross-sectional view showing a part of the lens LN1. The lens LN1 has an optical axis AX parallel to the Z-direction.

An intersection of the lens surface LS and a straight line L1 passing through the end portion E2 of the light shielding layer BM and inclined counterclockwise to the optical axis AX at an angle θ1 is defined as point P1. In the example shown in FIG. 7, the optical axis AX passes through the apex LT, and the straight line L1 passes through point P2, which is the intersection of the end portion E2 and the upper surface BS. At this time, the end portion E1 is located in an area between the point P1 and the apex LT. In one example, the angle θ1 is 45°.

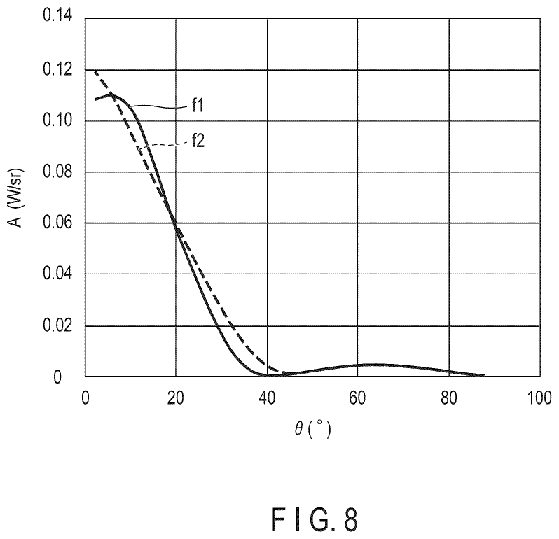

FIG. 8 is a graph showing the relationship between the angle θ and the luminance A. In the graph shown in FIG. 8, a horizontal axis indicates the angle θ relative to the Z-direction, and a vertical axis indicates the luminance A (radiation intensity) when viewed from the angle θ toward the display device DSP. When the angle θ is 0°, it corresponds to viewing the display device DSP from the front. A curve f1 represented by a solid line indicates the relationship between the angle θ and the luminance A in the display device DSP according to the present embodiment. A curve f2 represented by a dashed line indicates the relationship between angle θ and the luminance A in a display device DSP of a comparative example. The display device DSP of the comparative example does not have a low refractive index layer LRI, and the lens LN1 is directly covered with the adhesive layer AD.

In the graph shown in FIG. 8, the luminance A at the angle θ of approximately 20° to 45° is smaller for the curve f1 than that for the curve f2. In other words, in the display device DSP of the present embodiment, the viewing angle is more limited than that in the display device DSP of the comparative example.

The angle of refraction of the light on the lens surface LS increases as the refractive index difference between the lens LN1 and the layer covering the lens LN1 increases. In the present embodiment, the low refractive index layer LRI with a refractive index smaller than that of the adhesive layer AD and the lens LN1 covers part of the lens LN1. For this reason, the angle of refraction of the light on the lens surface LS in a case where the lens LN1 is covered with the low refractive index layer LRI having the refractive index smaller than that of the adhesive layer AD in the same manner as the present embodiment, becomes larger than that in a case where the lens LN1 is directly covered with the adhesive layer AD in the same manner as the display device DSP of the above-described comparative example. In other words, the viewing angle can be more limited in the display device DSP of the present embodiment. In addition, since the light emitted in an oblique direction from the display element DE1 is refracted to the front surface side, the luminance on the front surface side can be improved.

In addition, in the present embodiment, the apex LT of the lens LN1 is exposed from the low refractive index layer LRI. Even in such a case, since the light in the oblique direction is refracted at the interface between the lens LN1 and the low refractive index layer LRI, the viewing angle can be limited. Even if the height of the lens LN1 is large and it is difficult to completely cover the lens LN1 with the low refractive index layer LRI, the viewing angle can be limited by covering portions of the lens LN1 other than the apex LT with the low refractive index layer LRI, similarly to the present embodiment.

Furthermore, in the present embodiment, as shown in FIG. 7, the end portion E1 of the low refractive index layer LRI is located in the area between point P1 and the apex LT. Accordingly, the low refractive index layer LRI is provided on the optical path of the light emitted in the oblique direction from the display element DE1 and passing near the end portion E2 of the light shielding layer BM. As a result, the viewing angle can be limited.

Furthermore, in the present embodiment, the radius of curvature of the upper surface US1 of the low refractive index layer LRI is larger than the radius of curvature of the lens surface LS of the lens LN1. Therefore, the viewing angle can be limited as compared to the case where the radii of curvature of the upper surface US1 and the lens surface LS are the same.

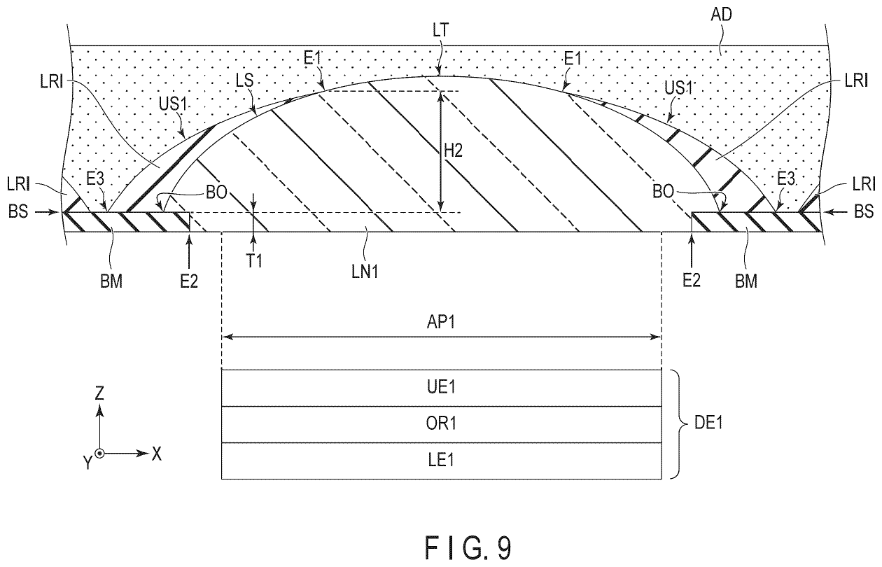

FIG. 9 is a schematic cross-sectional view showing another example of the low refractive index layer LRI. The low refractive index layer LRI shown in FIG. 9 does not have the upper surface US2 covering the light shielding layer BM, unlike the low refractive index layer LRI shown in FIG. 6. For this reason, the end portion E3 of the upper surface US1, which is located on a side opposite to the end portion E1, is located on the upper surface BS of the light shielding layer BM. In other words, a portion of the upper surface BS is exposed from the low refractive index layer LRI. The portion of the upper surface BS, which is exposed from the low refractive index layer LRI, is covered with the adhesive layer AD. In this configuration, the same effects as the above-described effects can also be obtained.

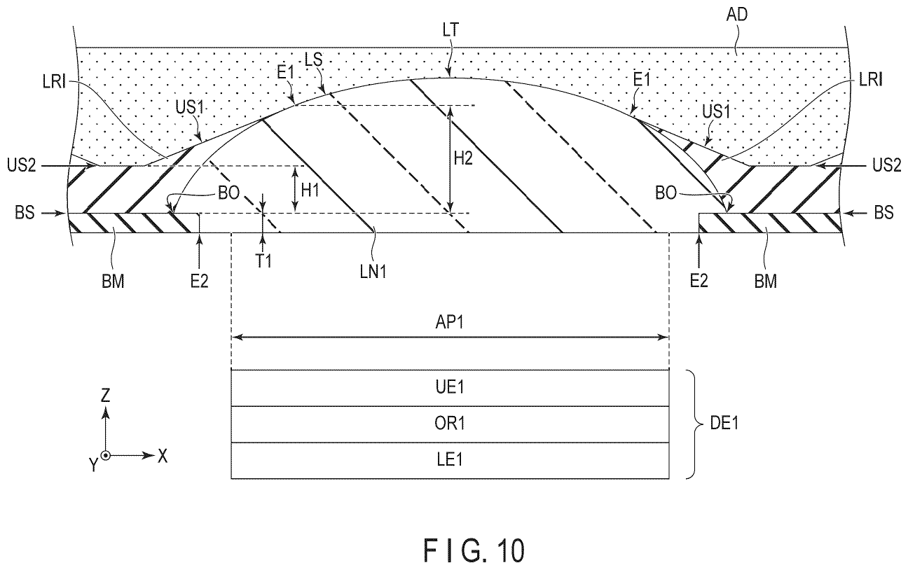

FIG. 10 is a schematic cross-sectional view showing yet another example of the low refractive index layer LRI. The low refractive index layer LRI shown in FIG. 10 is different from the low refractive index layer LRI shown in FIG. 6 in that a portion of the low refractive index layer LRI is tapered from the lens LN1 toward the light shielding layer BM. For this reason, the upper surface US1 is inclined from the lens LN1 toward the light shielding layer BM. In this configuration, the same effects as the above-described effects can also be obtained.

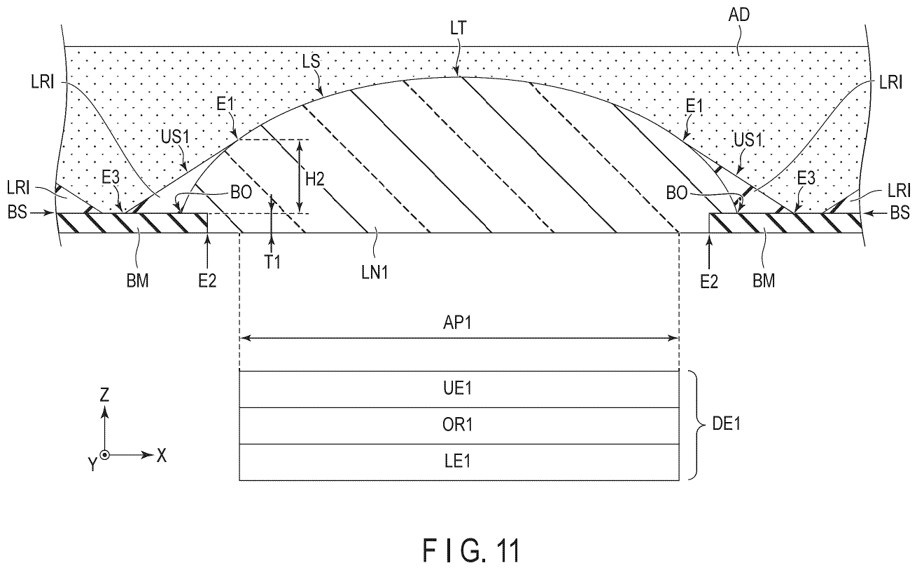

FIG. 11 is a schematic cross-sectional view showing yet another example of the low refractive index layer LRI. The low refractive index layer LRI shown in FIG. 11 does not have the upper surface US2, and the end portion E3 is located on the upper surface BS of the light shielding layer BM, unlike the low refractive index layer LRI shown in FIG. 10. In other words, a portion of the upper surface BS is exposed from the low refractive index layer LRI and this portion is covered with the adhesive layer AD. In this configuration, the same effects as the above-described effects can also be obtained.

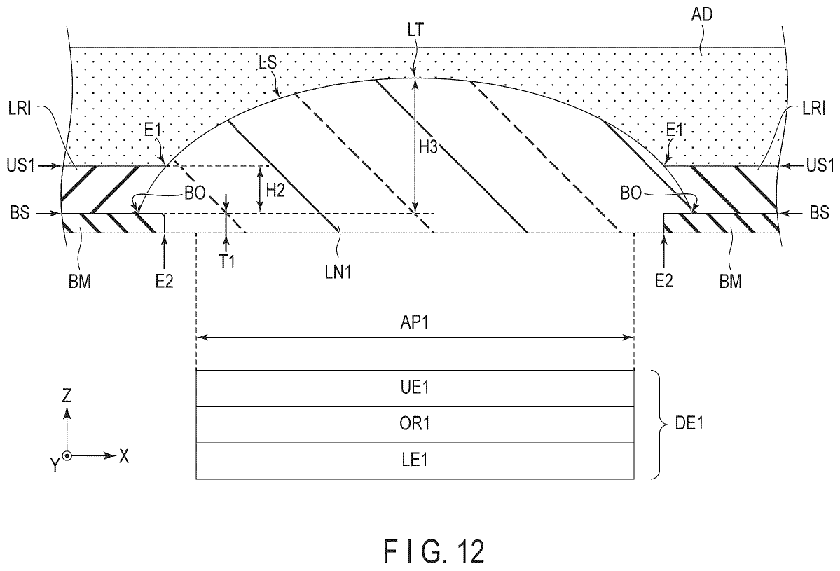

FIG. 12 is a schematic cross-sectional view showing yet another example of the low refractive index layer LRI. The low refractive index layer LRI shown in FIG. 12 is flat and covers the light shielding layer BM, unlike the low refractive index layer LRI shown in FIG. 6. In the example shown in FIG. 12, the upper surface US1 is parallel to the upper surface BS.

In the example of FIG. 12, the distance H2 in the Z-direction from the upper surface BS to the end portion E1 corresponds to the thickness of the low refractive index layer LRI. The distance H2 is shorter than the thickness T1 of the light shielding layer BM (H2<T1). The distance H2 is shorter than a distance H3 in the Z-direction from the upper surface BS to the apex LT. In this configuration, the same effects as the above-described effects can also be obtained.

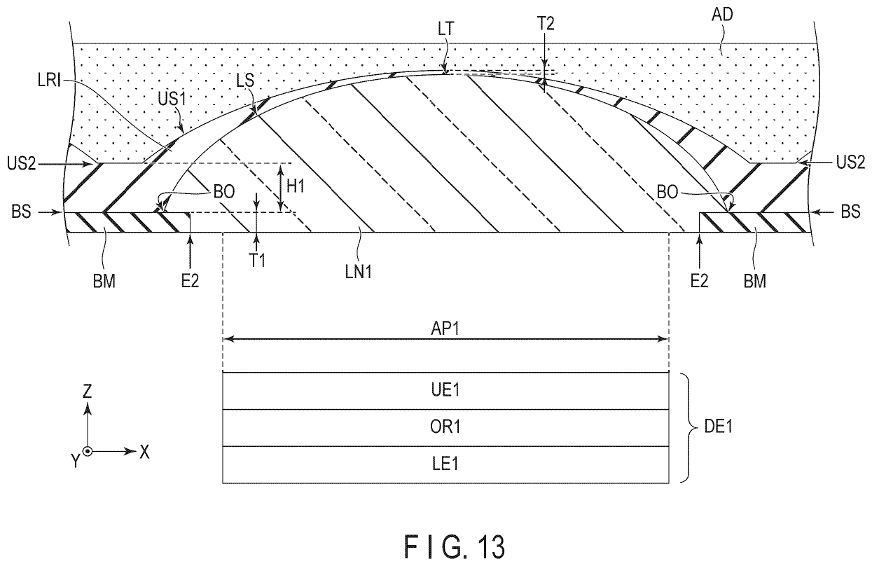

FIG. 13 is a schematic cross-sectional view showing yet another example of the low refractive index layer LRI. The low refractive index layer LRI shown in FIG. 13 covers the entire body of the lens LN1, unlike the low refractive index layer LRI shown in FIG. 6. In other words, the apex LT is covered with the low refractive index layer LRI.

The thickness of the low refractive index layer LRI decreases from the boundary BO toward the apex LT. In the example shown in FIG. 13, the thickness T2 of the low refractive index layer LRI at the apex LT is shorter than the distance H1 (T2<H1). In this configuration, the same effects as the above-described effects can also be obtained.

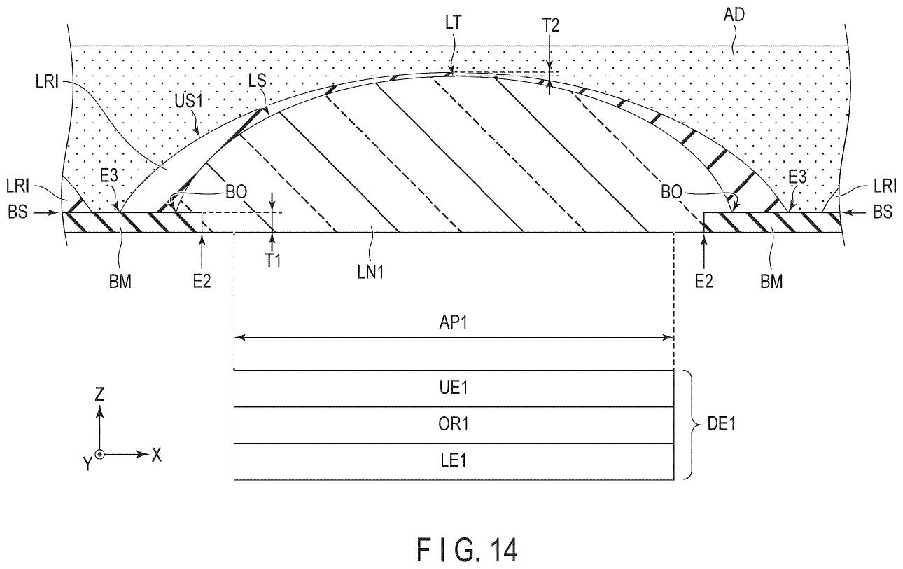

FIG. 14 is a schematic cross-sectional view showing yet another example of the low refractive index layer LRI. The low refractive index layer LRI shown in FIG. 14 does not have the upper surface US2, and the end portion E3 is located on the upper surface BS of the light shielding layer BM, unlike the low refractive index layer LRI shown in FIG. 13. In other words, a portion of the upper surface BS is exposed from the low refractive index layer LRI and this portion is covered with the adhesive layer AD. In this configuration, the same effects as the above-described effects can also be obtained.

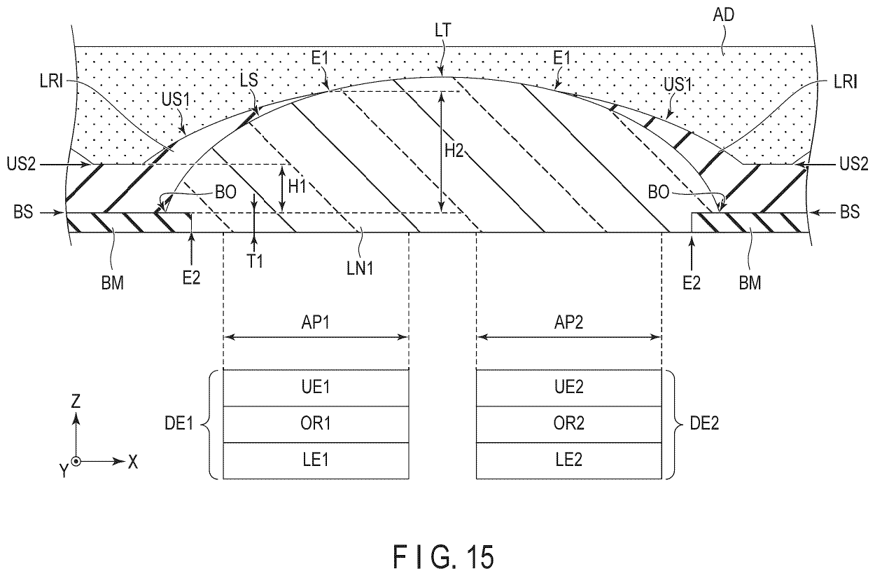

FIG. 15 is a schematic cross-sectional view showing an example in a case where the lens LN1 overlaps with the plurality of display elements DE1 and DE2.

In the example shown in FIG. 15, the lens LN1 overlaps with the display elements DE1 and DE2. In other words, the lens LN1 overlaps with the pixel apertures AP1 and AP2. The apex LT of the lens LN1 is provided between the pixel apertures AP1 and AP2 in plan view.

According to such a configuration, the light beam emitted from the display element DE1 is refracted on the lens surface LS to travel toward the right side in the figure. In contrast, the light beam emitted from the display element DE2 is refracted on the lens surface LS to travel toward the left side in the figure. Therefore, by supplying different image signals to the display elements DE1 and DE2, different images can be visually recognized when viewing the display device DSP from the right side and the left side in the figure.

Incidentally, in the example shown in FIG. 15, the organic layers OR1 and OR2 are configured to emit light of different colors, but may be configured to emit light of the same color. When the organic layers OR1 and OR2 are configured to emit light of the same color, the subpixels SP1, SP2, and SP3 of the arrangement shown in FIG. 2 and the subpixels SP1, SP2, and SP3 of an arrangement formed by laterally inverting this arrangement are alternately provided in the X-direction. As a result, different images can be visually recognized when viewing the display device DSP from the right side and the left side. In addition, the lens LN1 may overlap with three or more display elements (pixel apertures).

All of the display devices that can be implemented by a person of ordinary skill in the art through arbitrary design changes to the display device described above as the embodiments of the present invention come within the scope of the present invention as long as they are in keeping with the spirit of the present invention.

Various modified examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device comprising:
a substrate;
a first lower electrode;
a rib layer including a first pixel aperture overlapping with the first lower electrode;
a first organic layer in contact with the first lower electrode through the first pixel aperture;
a first upper electrode provided on the first organic layer;
a resin layer located above the first upper electrode;
a light shielding layer provided on the resin layer and overlapping with the rib layer;
a lens having a lens surface curved in a convex shape on a side opposite to the substrate, provided on the resin layer and the light shielding layer, and overlapping with the first pixel aperture; and
a low refractive index layer covering a boundary between the lens surface and an upper surface of the light shielding layer, exposing an apex of the lens, and having a refractive index lower than a refractive index of the lens.

2. The display device of claim 1, wherein
the low refractive index layer has a first upper surface that is curved in a convex shape on a side opposite to the substrate and that overlaps with the boundary, and
a radius of curvature of the first upper surface is greater than a radius of curvature of the lens surface.

3. The display device of claim 1, wherein
the low refractive index layer is tapered from the lens toward the light shielding layer.

4. The display device of claim 1, wherein
the low refractive index layer covers the light shielding layer and is flat.

5. The display device of claim 1, wherein
the low refractive index layer further has a first upper surface overlapping with the boundary, and a second upper surface overlapping with the light shielding layer, connecting to the first upper surface, and being flat.

6. The display device of claim 1, wherein
the low refractive index layer further has a first upper surface overlapping with the boundary, and a first end portion located on a boundary between the lens surface and the first upper surface,
the light shielding layer further has a second end portion covered with the lens, and
the first end portion is located in an area between the apex of the lens and an intersection of the lens surface and a straight line which passes through the second end portion and which is inclined at 45° relative to an optical axis of the lens.

7. The display device of claim 6, wherein
the second end portion overlaps with the rib layer.

8. The display device of claim 1, further comprising:
a second lower electrode arranged with the first lower electrode in a direction crossing an extension direction of the lens;
a second organic layer provided on the second lower electrode; and
a second upper electrode provided on the second organic layer, wherein
the rib layer further includes a second pixel aperture overlapping with the second lower electrode,
the second organic layer is in contact with the second lower electrode through the second pixel aperture, and
the lens overlaps with the second pixel aperture.

9. The display device of claim 8, wherein
an apex of the lens is provided between the first pixel aperture and the second pixel aperture in plan view.

10. The display device of claim 8, wherein
the first organic layer and the second organic layer are configured to emit light of colors different from each other.

11. A display device comprising:
a substrate;
a first lower electrode;
a rib layer including a first pixel aperture overlapping with the first lower electrode;
a first organic layer in contact with the first lower electrode through the first pixel aperture;
a first upper electrode provided on the first organic layer;
a resin layer located above the first upper electrode;
a light shielding layer provided on the resin layer and overlapping with the rib layer;
a lens having a lens surface curved in a convex shape on a side opposite to the substrate, provided on the resin layer and the light shielding layer, and overlapping with the first pixel aperture; and
a low refractive index layer provided on the lens and the light shielding layer, and having a refractive index lower than a refractive index of the lens, wherein
the low refractive index layer further has a first upper surface overlapping with the boundary between the lens surface and the upper surface of the light shielding layer, and a first end portion located on a boundary between the lens surface and the first upper surface,
the light shielding layer further has a second end portion covered with the lens, and
the first end portion is located in an area between the apex of the lens and an intersection of the lens surface and a straight line which passes through the second end portion and which is inclined at 45° relative to an optical axis of the lens.

12. The display device of claim 11, wherein the second end portion overlaps with the rib layer.

13. The display device of claim 11, further comprising:
a second lower electrode arranged with the first lower electrode in a direction crossing an extension direction of the lens;
a second organic layer provided on the second lower electrode; and
a second upper electrode provided on the second organic layer, wherein
the rib layer further includes a second pixel aperture overlapping with the second lower electrode, the second organic layer is in contact with the second lower electrode through the second pixel aperture, and
the lens overlaps with the second pixel aperture.

14. The display device of claim 13, wherein
an apex of the lens is provided between the first pixel aperture and the second pixel aperture in plan view.

15. The display device of claim 13, wherein
the first organic layer and the second organic layer are configured to emit light of colors different from each other.

16. The display device of claim 1, further comprising:
a partition including a conductive lower portion provided on the rib layer, and an upper portion provided on the lower portion to protrude from a side surface of the lower portion;
a cap layer covering the first upper electrode; and
a first sealing layer covering the cap layer and the partition, wherein
the rib layer is formed of an inorganic material,
the first upper electrode is in contact with the lower portion, and
the low refractive index layer overlaps with the partition.

17. The display device of claim 16, wherein
the resin layer includes a first resin layer covering the first sealing layer, a second sealing layer covering the first resin layer, and a second resin layer covering the second sealing layer, and
the light shielding layer and the lens are provided on the second resin layer.

18. The display device of claim 1, further comprising:
a polarizer provided above the lens and the low refractive index layer; and
an adhesive layer bonding the lens and the low refractive index layer to the polarizer.

19. The display device of claim 18, wherein
the adhesive layer covers the apex of the lens.

20. The display device of claim 18, wherein
the refractive index of the low refractive index layer is smaller than the refractive index of the adhesive layer.
